(19) United States
(12) Patent Application Publication
(10) Pub. No.: US 2026/0344538 A1
(43) Pub. Date: Oct. 29, 2026

(54) THREE-DIMENSIONAL STACKED FAN-OUT PACKAGE STRUCTURE AND PREPARATION METHOD THEREFOR

(71) Applicant: SJ Semiconductor(Jiangyin) Corporation, Jiangyin (CN)

(72) Inventors: Yenheng CHEN, Jiangyin (CN); Chengchung LIN, Jiangyin (CN); Jin YANG, Jiangyin (CN)

(73) Assignee: SJ Semiconductor(Jiangyin) Corporation, Jiangyin, JS (CN)

(21) Appl. No.: 19/107,589

(22) PCT Filed: Jun. 9, 2023
(86) PCT No.: PCT/CN2023/099289

§ 371 Date: Feb. 28, 2025

(30) Foreign Application Priority Data
Aug. 29, 2022 (CN) 202211037844.4

(51) Int. Cl. H10W 90/22; H10W 70/00; H10W 72/00; H10W 90/00; H10W 90/10; H10W 90/28

(52) U.S. Cl. CPC H10W 90/22; H10W 70/099; H10W 72/823; H10W 90/10; H10W 90/28; H10W 90/401

(57) ABSTRACT

A three-dimensional stacked fan-out package structure and a preparation method are disclosed. The structure comprises a chip stack body, a silicon adapter layer, a transmission chip, a cladding layer, and a substrate from top to bottom, the structure enables an electrical connection between the silicon adapter layer and the substrate by having a rewiring layer or a metal solder ball to carry out signal transmission. The transmission chip is set on the lower surface of the silicon adapter layer, and the chip stack body contains multiple chips on the silicon adapter layer. This structure improves the integration level, reduces the package volume, saves the substrate area, and makes it possible to accommodate a larger number of chips within a small area. The stacked design overlaps multiple chips, helping with heat transfer and heat dissipation.

### TECHNICAL FIELD

The present invention relates to the field of semiconductor packaging technology, and in particular relates to a three-dimensionally stacked fan-out packaging structure and a method for preparing the same.

### BACKGROUND

IC packaging has developed rapidly in recent years, flip chip electronic packaging as the mainstream packaging method takes 60-70% of the IC packaging market. For high-end flip chip packages, such as CPUs for servers, AI and HPC, multi-chip integration is needed, which requires multiple chips to be placed on a single substrate. The flip-flop fan-out package structure includes a variety of chip types, including core die, IO die, cache/SRAM die, and structure die. As the number of cores and functional complexity of such high-performance chips increase, more of them need to be integrated onto a single substrate. As shown in FIGS. 1 and 2, in the existing technique, the substrate 302 is formed with the transmission chip 122 and the first chips 201, and the transmission chip 122 and the first chip 201 are sequentially laid flat on the surface of the substrate 302, and in order to accommodate a larger number of chips, it is inevitable to increase the area of the substrate, which also induces a rapid increase in the size of the substrate from 50×50 mm² to 100×100 mm². However, as the size of the substrate increases, so does its cost plus scrap rate, which hinders the application of large-size substrates.

Therefore, there is a need to propose a package structure to accommodate a larger number of chips even with the existing small size substrate.

### SUMMARY

The present disclosure provides a three-dimensionally stacked fan-out package structure, this fan-out package structure comprises:
a silicon adapter layer, the silicon adapter layer having a transmission chip bonded to the lower surface of the silicon adapter layer;
a cladding layer, the cladding layer encompassing a side wall of the transmission chip, and the cladding layer having a first conductive post running through the cladding layer;
a chip stack body, the chip stack body being bonded to the upper surface of the silicon adapter layer, the chip stack body comprising 2 or more chips stacked in a vertical direction, with signal transmission between adjacent chip stack bodies via the transmission chip; and
a substrate, the substrate being provided below the cladding layer and electrically connected to the silicon adapter layer via the first conductive post.

Preferably, a rewiring layer is formed on the lower surface of the cladding layer, the rewiring layer comprising a wiring media layer and a metal wiring layer disposed within the wiring media layer.

Preferably, the rewiring layer is bonded to the substrate via a bonding adhesive layer; the bonding adhesive layer is provided with a second conductive post, and the substrate is electrically connected to the silicon adapter layer via the second conductive post, the metal wiring layer, and the first conductive post in turn.

Preferably, the transmission chip is electrically connected to the substrate via the rewiring layer and second conductive post.

Preferably, the cladding layer also covers the lower surface of the transmission chip; the cladding layer is connected to the substrate by means of a metal solder ball, and the substrate is electrically connected to the silicon adapter layer by means of the metal solder ball, the first conductive column and the silicon adapter layer in turn.

The present invention also provides a method of preparing a fan-out package structure with three-dimensional stacking, comprising the following steps:
S1: providing a silicon adapter layer, the silicon adapter layer having a transmission chip bonded to a lower surface of the silicon adapter layer;
S2: forming a cladding layer on a lower surface of the silicon adapter layer, the cladding layer covering a side wall of the transmission chip, and the cladding layer having a first conductive post running through the cladding layer;
S3: bonding a chip stack on the upper surface of the silicon adapter layer, the chip stack comprising 2 or more chips stacked in a vertical direction, and signal transmission between adjacent chip stacks via the transmission chip;
S4: connecting a substrate underneath the cladding layer, the substrate being electrically connected to the silicon adapter layer via a first conductive post.

Preferably, after step S3, the rewiring layer is formed on the lower surface of the cladding layer, the rewiring layer comprising a wiring medium layer and a metal wiring layer disposed within the wiring medium layer.

Preferably, after forming the rewiring layer, the rewiring layer is bonded to the substrate by means of a bonding adhesive layer; the bonding adhesive layer is provided with a second conductive post, and the substrate is electrically connected to the silicone adapter layer sequentially by means of the second conductive post, the metal wiring layer, and the first conductive post.

Preferably, the transmission chip is electrically connected to the substrate via the rewiring layer and second conductive post.

Preferably, in step S2, the cladding layer also attaches the lower surface of the transmission chip; the cladding layer is connected to the substrate by means of a metal solder ball, and the substrate is electrically connected to the silicon adapter layer sequentially by means of the metal solder ball, the first conductive column and the silicon adapter layer.

As described above, the present invention provides a three-dimensional stacked fan-out package structure and a preparation method thereof, the fan-out package structure comprising a chip stack body, a silicon adapter layer, a transmission chip, a cladding layer, and a substrate, in order from top to bottom, and realizing an electrical connection between the silicon adapter layer and the substrate by setting up a rewiring layer or a metal solder ball so as to carry out signal transmission. Among them, the transmission chip is set on the lower surface of the silicon adapter layer, and the chip stack containing a plurality of chips is set on the upper surface of the silicon adapter layer, which improves the integration degree of the entire structure, reduces the package volume, saves the substrate area, and makes it possible to accommodate a larger number of chips on the substrate with a small area; the stacked design makes the chips overlap each other, which is also conducive to the heat transfer, thus improving the heat dissipation The stacked design makes the chips overlap each other, which is also favorable for heat transfer, thus improving the heat dissipation effect. Therefore, the present invention effectively overcomes the shortcomings of the prior art and has high industrial utilization value.

### BRIEF DESCRIPTION OF THE DRAWINGS

FIG. 1 shows a schematic diagram of a top view structure of an existing chip arrangement.

FIG. 2 shows a schematic diagram of a side view structure of the existing chip arrangement.

FIG. 3 shows a schematic diagram of the structure of the silicon adapter layer.

FIG. 4 shows a schematic diagram of a structure for forming a cladding layer.

FIG. 5 shows a schematic diagram of the structure of the first chip bonded to the wafer.

FIG. 6 shows a schematic diagram of the structure of a chip stack body formed by cutting a wafer.

FIG. 7 shows a schematic view of a structure forming a rewiring layer.

FIG. 8 shows a schematic view of the structure after cutting.

FIG. 9 shows a schematic view of a structure bonded to a substrate.

FIG. 10 shows a schematic diagram of the setup of a metal solder ball.

FIG. 11 shows a schematic top view of the fan-out package structure of the present invention.

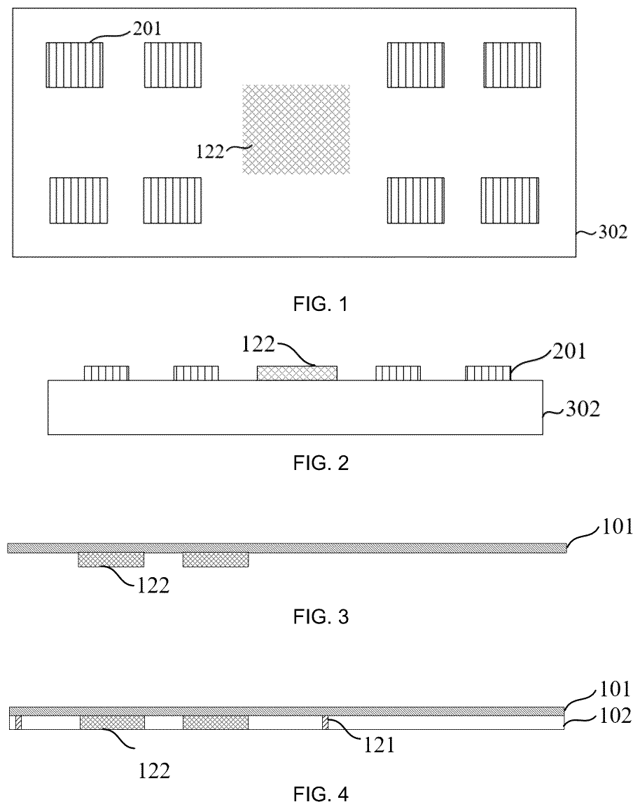

Component labeling

| | |
|---|---|
| 101 | silicon adapter layer |
| 102 | coating layer |
| 121 | first conductive column |
| 122 | transport chip |
| 302 | substrates |
| 201 | first chip |
| 202 | second chip |
| 103 | rewiring layer |
| 311 | metal solder ball |
| 131 | metal wiring layer |
| 132 | Wiring Media Layer |
| 301 | bonding layer |
| 312 | Second conductive column |
| 2021 | wafers |

### DETAILED DESCRIPTION OF THE PREFERRED EMBODIMENTS

Embodiments of the present invention are hereinafter described by way of particular specific examples, and other advantages and efficacies of the present invention can be readily appreciated by those skilled in the art from what is disclosed in this specification. The present invention may also be implemented or applied in different other specific embodiments, and various details in this specification may also be modified or changed in various ways based on different views and applications without departing from the spirit of the present invention.

As in the detailed description of the embodiments of the present invention, for the sake of illustration, the sectional drawings representing the structure of the device will not be partially enlarged in accordance with the general scale, and the schematic drawings are only exemplary, which shall not limit the scope of protection of the present invention herein. In addition, three-dimensional spatial dimensions of length, width and depth should be included in the actual production.

For ease of description, spatial relationship terms such as “under,” “below,” “below,” “below,” “below,” “above,” “above,” “above,” and the like may be used herein to describe the relationship of an element or feature shown in the accompanying drawings to other elements or features, “above,” “on,” and the like to describe the relationship of one element or feature shown in the accompanying drawings to other elements or features. It will be appreciated that these spatial relationship terms are intended to encompass orientations of the device in use or operation other than those depicted in the accompanying drawings. Furthermore, when a layer is the to be “between” two layers, it may be the only layer between the two layers, or there may be one or more intervening layers. The term “between . . . ” is used in this document to include both endpoint values.

In the context of the present application, the described structure with the first feature “on top” of the second feature may include embodiments in which the first and second features are formed in direct contact, and may also include embodiments in which additional features are formed between the first and second features, such that the first and second features may not be in direct contact.

It is to be noted that the illustrations provided in this embodiment only illustrate the basic concept of the present invention in a schematic manner, so the illustrations only show the components related to the present invention and are not drawn in accordance with the actual implementation of the number of components, shapes and sizes of the actual implementation of the components of the type, number and proportion of the actual implementation of the components may be an arbitrary change, and the layout of the components of the type may be more complex.

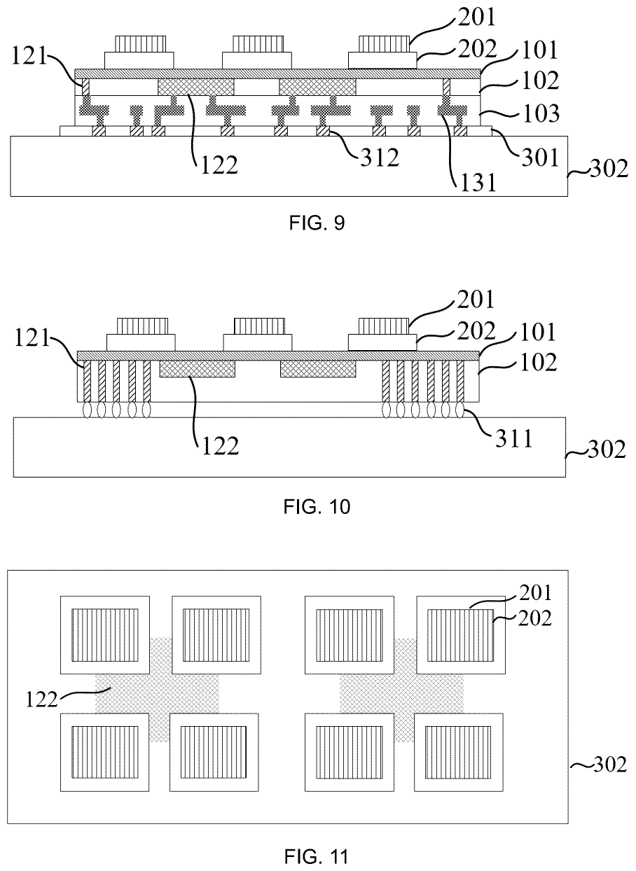

The present embodiment provides a method of preparing a fan-out package structure with three-dimensional stacking, comprising the following steps:
S1: A silicon adapter layer 101 is provided, the silicon adapter layer 101 having a transmission chip 122 bonded to the lower surface of the silicon adapter layer 101, as shown in FIG. 3;
S2: A cladding layer 102 is formed on the lower surface of the silicon adapter layer 101, the cladding layer 102 is attached to the sidewall of the transmission chip 122, and the cladding layer 102 is provided with a first conductive post 121 disposed through the cladding layer 102 as shown in FIG. 4;
S3: bonding a chip stack body on the upper surface of the silicon adapter layer 101, the chip stack body comprising 2 more chips stacked in a vertical direction, with signal transmission between adjacent chip stack bodies via the transmission chip 122, as shown in FIG. 7;
S4: A substrate 302 is provided below the cladding layer 102, and the substrate 302 is electrically connected to the silicon adapter layer 101 via a first conductive post 121, as shown in FIGS. 9 and 10.

Specifically, the silicon adapter layer 101, i.e., silicon interposer, is provided with TSV vias inside the silicon layer as a conductive channel between the chip stack above and the device below, and the transmission chip 122 may be an IO chip for transmission of IO signals between adjacent chip stacks above. The chip stack in this embodiment includes a first chip 201 and a second chip 202, the first chip 201 may be a core processing chip (core die), the second chip 202 may be a cache chip (cache die), it should be understood that the type of the first chip 201 and second chip 202 is not limited to this, and the chips in the chip stack are not limited to 2 layers, but can also be 3 or 4 layers. Individual chips in the chip stack have electrical connections between them for signal transmission, for example between the first chip 201 and second chip 202. As shown in FIG. 11, the transmission chip 122 may be used for signaling between 2 adjacent chip stacks or for signaling between 4 or more adjacent chip stacks, without being overly limited herein, the substrate 302 may be a glass substrate, a ceramic substrate, a metal substrate, an organic polymer substrate, and other materials. In addition, after step S3, a process of cutting (i.e., singulation) may be included to cut and separate the unwanted portions, as shown in FIG. 8.

The present invention improves the integration of the whole structure by setting the transmission chip 122 on the lower surface of the silicon adapter layer 101 and at the same time setting a chip stack containing a plurality of chips on the upper surface of the silicon adapter layer 101, which makes it possible to accommodate a higher number of chips even on a small area of the substrate. In addition, the use of stacked design makes the chips overlap each other, which is also conducive to heat transfer, thus improving heat dissipation.

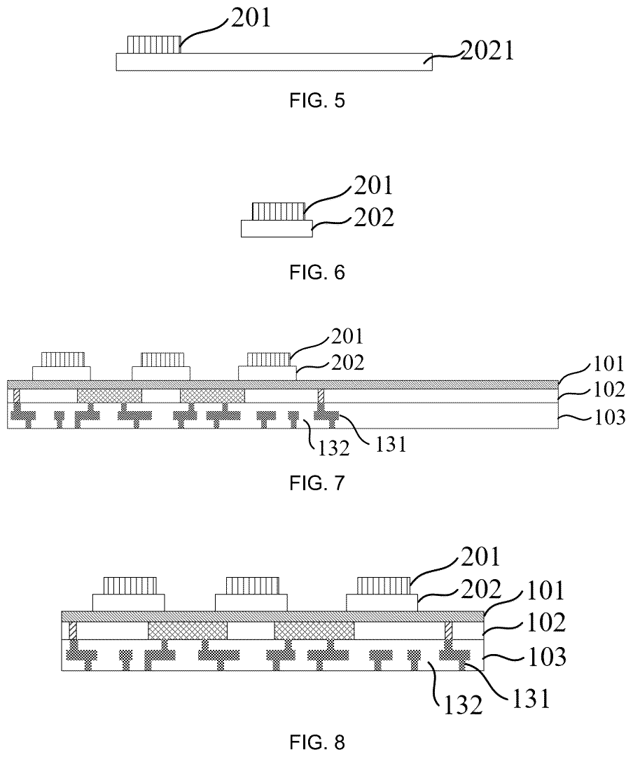

Specifically, as shown in FIG. 5-FIG. 6, the first chip 201 is bonded to the wafer 2021, and then the wafer 2021 is diced (i.e., singulation) in order to cut and separate unwanted portions, ultimately forming the chip stack body.

Optionally, in step S4, the substrate 302 is electrically connected to the silicon adapter layer 101 through a rewiring layer 103 connection or a metal solder ball 311, in addition to being electrically connected through the first conductive post 121, as shown in FIGS. 9-FIG. 10.

Optionally, as shown in FIG. 7, after step S3, the rewiring layer 103 is formed on the lower surface of the cladding layer 102, the rewiring layer 103 comprising a wiring media layer 132 and a metal wiring layer 131 disposed within the wiring media layer 132. The material of the wiring media layer 132 comprises one or a combination of two or more of the group consisting of epoxy resin, silicone, PI, PBO, BCB, silicon oxide, phosphor-silicon glass, and fluorine-containing glass; and the material of the metallic wiring layer 131 comprises one or a combination of two or more of the group consisting of copper, aluminum, nickel, gold, silver, and titanium. The material, number of layers, and distribution morphology of the wiring medium layer 132 and metal wiring layer 131 may be set according to the specific conditions of the semiconductor chip, and are not limited herein.

Further, as shown in FIG. 9, after forming the rewiring layer 103, the rewiring layer 103 is bonded to the substrate 302 via bonding adhesive layer 301. the bonding adhesive layer 301 is provided with a second conductive post 312, and the substrate 302 is electrically connected to the silicon adapter layer 101 through the second conductive post 312, the metal wiring layer 131, and the first conductive post 121 in turn. Optionally, the transmission chip 122 may also be electrically connected to the substrate 302 via the rewiring layer 103 and second conductive post 312. Wherein, the material of the first conductive column 121 and the second conductive column 312 may be one of copper, aluminum, nickel, gold, silver, tin, titanium, or one of two or more alloy materials, and the cladding layer 102 and the bonding adhesive layer 301 may be one of polyimide, silicone, and epoxy resin or a combination of any of them.

Optionally, in step S2, the cladding layer 102 also wraps around the lower surface of the transmission chip 122 to form a protection, i.e. the thickness of the cladding layer 102 is greater than the thickness of the transmission chip 122. As shown in FIG. 10, after step S3, the cladding layer 102 is connected to the substrate 302 by means of a metal solder ball 311, and the substrate 302 is electrically connected to the silicon adapter layer 101 by the order of the metal solder ball 311, the first conductive post 121, and the silicon adapter layer 101. Wherein the metal solder ball 311, in addition to being used to realize an electrical connection, is also capable of ensuring that there is a gap between the cladding layer 102 and the substrate 302. The material of the metal solder ball 311 may be one of copper, aluminum, nickel, gold, silver, titanium or a combination of two or more such materials.

Based on the above preparation method, the present embodiment also provides a three-dimensional stacked fan-out encapsulation structure, as shown in FIG. 9-FIG. 10, the fan-out encapsulation structure comprising:
a silicon adapter layer 101, the silicon adapter layer 101 having a transmission chip 122 bonded to the lower surface of the silicon adapter layer 101;
a cladding layer 102, the cladding layer 102 encompassing a side wall of the transmission chip 122, and the cladding layer 102 containing a first conductive post 121 running through the cladding layer 102;
a chip stack body, the chip stack body being bonded to the upper surface of the silicon adapter layer 101, the chip stack body comprising 2 or more chips stacked in a vertical direction, with signal transmission between neighboring chip stack bodies via the transmission chip 122; and
a substrate 302, the substrate 302 being electrically connected to the silicon adapter layer 101 via the first conductive post 121.

Specifically, the silicon adapter layer 101, i.e., silicon interposer, is provided with TSV vias inside the silicon layer as a conductive channel between the chip stack above and the device below, and the transmission chip 122 may be an IO chip for transmission of IO signals between adjacent chip stacks above. The chip stack in this embodiment includes a first chip 201 and a second chip 202, the first chip 201 may be a core processing chip (core die), the second chip 202 may be a cache chip (cache die), it should be understood that the type of the first chip 201 and second chip 202 is not limited to this, and the chips in the chip stack are not limited to 2 layers, but can also be 3 or 4 layers or more. Individual chips in the chip stack have electrical connections between them for signal transmission, for example between the first chip 201 and second chip 202. As shown in FIG. 11, the transmission chip 122 may be used for signaling between 2 adjacent chip stacks or for signaling between 4 or more adjacent chip stacks, without being overly limited herein. the substrate 302 may be a glass substrate, a ceramic substrate, a metal substrate, an organic polymer substrate, and other materials.

The present invention improves the integration of the whole structure by setting the transmission chip 122 on the lower surface of the silicon adapter layer 101 and at the same time setting a chip stack body containing a plurality of chips on the upper surface of the silicon adapter layer 101, which makes it possible to accommodate a higher number of chips even on a small area of the substrate. In addition, the use of stacked design makes the chips overlap each other, which is also conducive to heat transfer, thus improving heat dissipation.

Optionally, the substrate 302 is electrically connected to the silicon adapter layer 101 through a rewiring layer 103 connection or a metal solder ball 311, in addition to being electrically connected through the first conductive post 121.

Optionally, as shown in FIG. 9, a rewiring layer 103 is formed on the lower surface of the cladding layer 102, the rewiring layer 103 comprising a wiring media layer 132 and a metal wiring layer 131 disposed within the wiring media layer 132. The material of the wiring media layer 132 comprises one or a combination of two or more of the group consisting of epoxy resin, silicone, PI, PBO, BCB, silicon oxide, phosphor-silicon glass, and fluorine-containing glass; and the material of the metallic wiring layer 131 comprises one or a combination of two or more of the group consisting of copper, aluminum, nickel, gold, silver, and titanium. The material, number of layers, and distribution morphology of the wiring medium layer 132 and metal wiring layer 131 may be set according to the specific conditions of the semiconductor chip, and are not limited herein.

Further, the rewiring layer 103 is bonded to the substrate 302 via a bonding adhesive layer 301. the bonding adhesive layer 301 is provided with a second conductive post 312, and the substrate 302 is electrically connected to the silicon adapter layer 101 through the second conductive post 312, the metal wiring layer 131, and the first conductive post 121 in turn. Optionally, the transmission chip 122 may also be electrically connected to the substrate 302 via the rewiring layer 103 and second conductive post 312. Wherein, the material of the first conductive column 121 and the second conductive column 312 may be one of copper, aluminum, nickel, gold, silver, tin, titanium, or one of two or more alloy materials, and the cladding layer 102 and the bonding adhesive layer 301 may be one of polyimide, silicone, and epoxy resin or a combination of any of them.

Optionally, as shown in FIG. 10, the cladding 102 also wraps around the lower surface of the transmission chip 122 to form a protection, i.e., the thickness of the cladding 102 is greater than the thickness of the transmission chip 122. the cladding layer 102 is connected to a substrate 302 by means of a metal solder ball 311, and the substrate 302 is electrically connected to the silicon adapter layer 101 in turn by means of the metal solder ball 311, the first conductive post 121. Wherein the metal solder ball 311, in addition to being used to realize an electrical connection, is also capable of ensuring that there is a gap between the cladding layer 102 and the substrate 302. The material of the metal solder ball 311 may be one of copper, aluminum, nickel, gold, silver, titanium or a combination of two or more materials.

In summary, the present invention provides a three-dimensional stacked fan-out package structure and a preparation method thereof. The fan-out package structure comprises a chip stack body, a silicon adapter layer, a transmission chip, a cladding layer, and a substrate, in the order from top to bottom, and it realizing an electrical connection between the silicon adapter layer and the substrate by setting a rewiring layer or a metal solder ball so as to carry out signal transmission. Among them, the transmission chip is set on the lower surface of the silicon adapter layer, and the chip stack containing a plurality of chips is set on the upper surface of the silicon adapter layer, which improves the integration level of the entire structure, reduces the package volume, saves the substrate area, and makes it possible to accommodate a larger number of chips on the substrate with a small area; the stacked design makes the chips overlap each other, which is also conducive to the heat transfer, thus improving the heat dissipation. The stacked design makes the chips overlap each other, which is also favorable for heat transfer, thus improving the heat dissipation result. Therefore, the present invention effectively overcomes the shortcomings of the existing techniques and has high industrial utilization value.

The foregoing embodiments are only illustrative of the principles of the present invention and its efficacy and are not intended to limit the invention. Any person skilled in the art may modify or change the above embodiments without violating the spirit and scope of the present invention. Accordingly, all equivalent modifications or alterations accomplished by persons having ordinary knowledge in the art without departing from the spirit and technical ideas disclosed herein shall still be covered by the claims of the present invention.

1. A fan-out package structure stacked three-dimensionally, comprising:
a silicon adapter layer, wherein the silicon adapter layer includes a transmission chip bonded to a lower surface of the silicon adapter layer;
a cladding layer, wherein the cladding layer encompasses a side wall of the transmission chip, and wherein the cladding layer includes a first conductive post placed through the cladding layer;
a chip stack body, wherein the chip stack body is bonded to an upper surface of the silicon adapter layer, wherein the chip stack body comprises 2 or more chips stacked in a vertical direction, and wherein a signal transmission between adjacent chips in the chip stack body travels via the transmission chip; and
a substrate, wherein the substrate is displaced below the cladding layer and electrically connected to the silicon adapter layer via the first conductive post.

2. The fan-out package structure according to claim 1, comprising a rewiring layer formed on a lower surface of the cladding layer, wherein the rewiring layer comprises a wiring medium layer and a metal wiring layer which is disposed within the wiring medium layer.

3. The fan-out package structure according to claim 2, wherein the rewiring layer is bonded to the substrate via a bonding adhesive layer; wherein the bonding adhesive layer is provided with a second conductive post, and wherein the substrate is also electrically connected to the silicon adapter layer via the second conductive post, the metal wiring layer, and the first conductive post sequentially.

4. The fan-out package structure according to claim 3, wherein the transmission chip is electrically connected to the substrate via the rewiring layer and the second conductive post.

5. The fan-out package structure according to claim 1, wherein the cladding layer also clads the lower surface of the transmission chip; wherein the cladding layer and the substrate are connected by means of a metal soldering ball, and wherein the substrate is electrically connected to the silicon adapter layer by means of the metal soldering ball, the first conductive column and the silicon adapter layer sequentially.

6. A method of preparing a fan-out package structure stacked three-dimensionally, comprising steps of:
S1: providing a silicon adapter layer, wherein the silicon adapter layer includes a transmission chip bonded to a lower surface of the silicon adapter layer;
S2: forming a cladding layer on the lower surface of the silicon adapter layer, wherein the cladding layer covers a side wall of the transmission chip, and wherein the cladding layer comprises a first conductive post displaced through the cladding layer;
S3: bonding a chip stack body on an upper surface of the silicon adapter layer, wherein the chip stack body comprises 2 or more chips stacked in a vertical direction, and signal transmission between adjacent chips in the chip stack body travels via the transmission chip; and
S4: connecting a substrate underneath the cladding layer, wherein the substrate is electrically connected to the silicon adapter layer via a first conductive post.

7. The method of preparation the fan-out package structure according to claim 6, further comprises, after step S3, forming the rewiring layer on a lower surface of the cladding layer, wherein the rewiring layer comprises a wiring medium layer and a metal wiring layer disposed within the wiring medium layer.

8. The method of preparation the fan-out package structure according to claim 7, further comprising, after forming the rewiring layer, bonding the rewiring layer to the substrate by means of a bonding adhesive layer; wherein the bonding adhesive layer comprises a second conductive column, and wherein the substrate is electrically connected to the silicon adapter layer through the second conductive column, the metal wiring layer, and the first conductive column sequentially.

9. The method of preparation the fan-out package structure according to claim 8, further comprising electrically connecting the transmission chip to the substrate through the rewiring layer and second conductive post.

10. The method of preparation the fan-out package structure according to claim 6, further comprising: in step S2, attaching the cladding layer to a lower surface of the transmission chip; wherein the cladding layer and the substrate are connected by metal solder balls, and wherein the substrate is electrically connected to the silicon adapter layer through the metal solder balls, the first conductive column and the silicon adapter layer sequentially.
